(19) United States
(12) Patent Application Publication
(10) Pub. No.: US 2006/0208829 A1
(43) Pub. Date: Sep. 21, 2006

(54) System and method for timer windows

(75) Inventors: Robert H. Earhart, Snohomish, WA (US); Grigori V. Kapoustin, Bellevue, WA (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Microsoft Corporation, Redmond, WA (US)

(21) Appl. No.: 11/081,263

(22) Filed: Mar. 15, 2005

(51) Int. Cl. H03H 9/70

(52) U.S. Cl. 333/133

(57) ABSTRACT

A system and method for timer windows is provided. A mechanism is provided for managing actions that need to be started within a specified interval. By exploiting windows of acceptable times for events, timer expirations can be grouped and processed in batches to improve the throughput of the system. For one embodiment, an event is associated with a timer object, which has start and end times that specify an interval during which the associated event should be started. A pair of priority queues prioritizes timers by earliest start times and earliest end times. These times are compared with the current time, and corresponding timers are retired from the queue until the timer at the front of the queue has a start time that is later than the current time.

### FIELD OF THE INVENTION

The embodiment of the present invention relates to timers, and more particularly, to a system and method for timer windows.

### BACKGROUND OF THE INVENTION

Many systems provide a facility for scheduling an action to occur after some specified due time. Many such actions may be scheduled at once, with varying due times. This may require the processor to spend additional time doing context swapping.

The embodiment of the present invention is directed to providing a system and method that overcomes the foregoing and other disadvantages. More specifically, the present invention is directed to a system and method for timer windows.

### SUMMARY OF THE INVENTION

A system and method for timer windows is provided. Many systems provide a facility for scheduling an action to occur after some specified due time. Frequently, it is less important that the action commences as soon as possible after the specified time. There is a window of acceptable delay. In accordance with one aspect of the present invention, a mechanism is provided for managing actions that need to occur only in a specified interval. By exploiting windows of acceptable times for events, timer expirations can be grouped and processed in batches to improve the throughput of the system. In one embodiment, an action is associated with a timer object, which has start and end times that specify an interval during which the associated action should be started. A pair of priority queues prioritizes timers by earliest start times and earliest end times. These times are compared with the current time, and corresponding timers are retired from the queue until the timers at the front of the queues have a start time that is later than the current time. The timer windows provide an interface for specifying a window of time in which a timer's action should be started, and an implementation which efficiently groups expiring timers into batches for processing. This reduces the amount of time the processor spends context swapping, resulting in higher overall throughput.

In accordance with another aspect of the invention, a window start priority queue and a window end priority queue are utilized. The timers are ordered by their window start times and their window end times. A single underlying timer object is used to wait until it becomes necessary to perform an action (for a kernel, this may be a hardware timer; or for an application, this may be a kernel-mode timer).

In accordance with another aspect of the invention, in order to determine the underlying timer's expiration time, the window end priority queue of all of the currently active timers ordered by their earliest window end times is used. The expiration time of the timer at the front of the queue (the timer with the earliest window end time) is the latest time at which the underlying timer can fire and still provide correct behavior. This is used for the expiration time of the underlying timer.

In accordance with another aspect of the invention, when the underlying timer expires and the system timers are being expired, the window end priority queue may be insufficient in that there may be timers which can and should be expired, but whose window end times are later than the window end times of timers which should not be expired. Thus, the window start priority queue of the currently active timers ordered by their earliest start times first is also maintained. To expire timers, the implementation dequeues timers from the window start queue until the timer at the front of the queue has a window start time later than the current time.

In accordance with another aspect of the invention, as an optimization, timers with zero-length windows may be linked only into the window end queue. This reduces the overhead for a zero-length window timer to a single priority queue insertion and removal. With this optimization, when expiring timers, the timers at the fronts of both the window start queue and the window end queue must be expired, until the timers at the front of both queues have a window start time later than the current time.

It will be appreciated that the overhead of maintaining two timer queues instead of one is relatively small. The asymptotic performance is the same, and the working set of data will tend to be similar.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a flow diagram illustrative of a general routine for utilizing two priority queues for ordering timers;

FIG. 2 is a flow diagram illustrative of a routine for determining an underlying timer's expiration time;

FIG. 3 is a flow diagram illustrative of a routine for expiring timers;

FIG. 4 is a flow diagram illustrative of a routine for a timer with a zero-length window; and

FIG. 5 is a timing diagram illustrating multiple timers with varying window start and end times.

### DETAILED DESCRIPTION OF THE PREFERRED EMBODIMENT

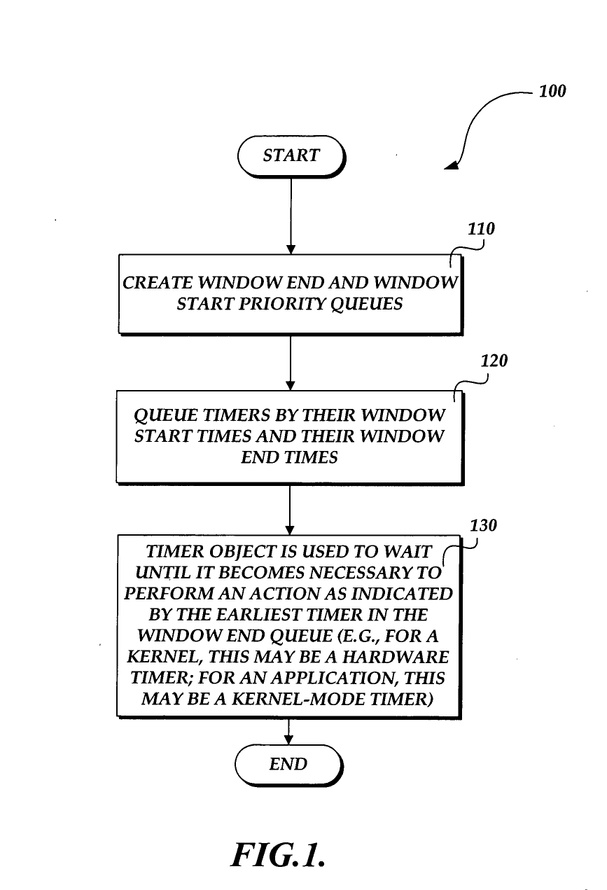

FIG. 1 is a flow diagram illustrative of a general routine 100 for timer windows utilizing window start and window end priority queues. At a block 110, window end and window start priority queues are created. At a block 120, the timers are ordered by their window start times and their window end times. At a block 130, the timer object is used to wait until it becomes necessary to perform an action (e.g., for a kernel, this may be a hardware timer, while for an application, this may be a kernel-mode timer).

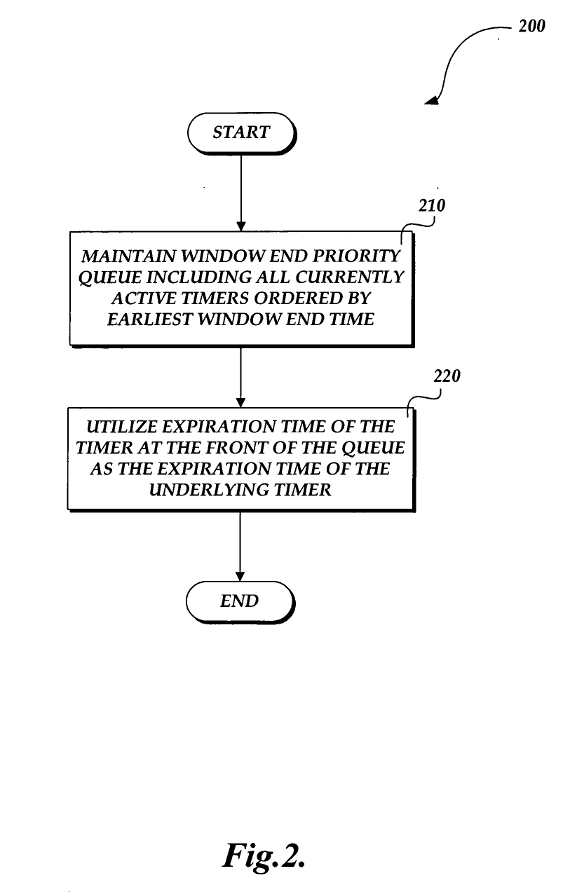

FIG. 2 is a flow diagram illustrative of a routine 200 for determining the underlying timer's expiration time. At a block 210, a window end priority queue is maintained including all of the currently active timers ordered by the earliest window end time. At a block 220, the expiration time of the timer at the front of the queue is utilized as the expiration time of the underlying timer. In other words, the expiration time of the timer at the front of the queue is the latest time at which the underlying timer can fire and still provide correct behavior.

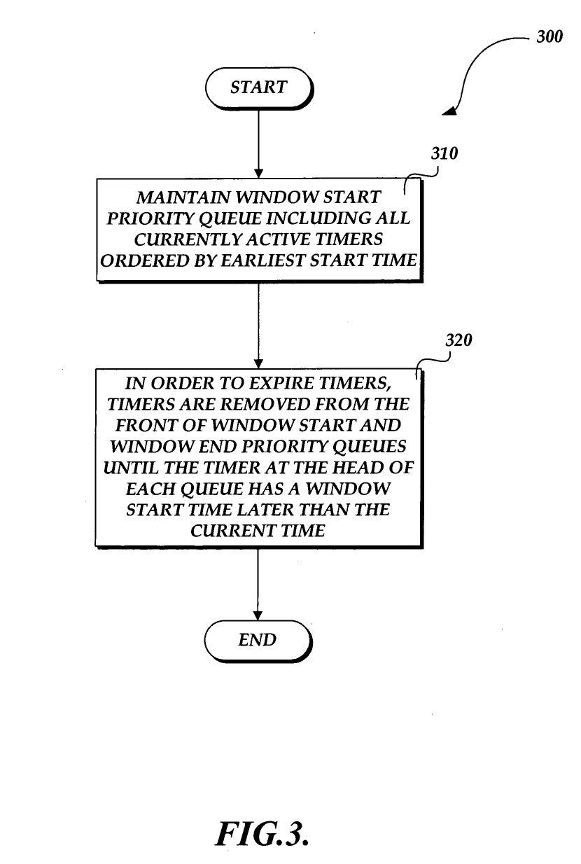

FIG. 3 is a flow diagram illustrative of a routine 300 for expiring timers. At a block 310, the window start priority queue is maintained including all of the currently active timers ordered by the earliest start time. At a block 320, in order to expire the timers, the timers are removed from the front of the window start and window end priority queues until the timers at the front of each queue have a window start time later than the current time. In other words, when the underlying timer expires and the system timers are being expired, the window end priority queue may be insufficient, in that there may be timers which can and should be expired, but whose window end times are later than the window end times of timers which should not be expired. Thus, the implementation also maintains the window start priority queue of the currently active timers ordered by their earliest start time first. As noted above, to expire the timers, the implementation removes timers from the window start and window end priority queues until the timer at the front of each queue has a window start time later than the current time.

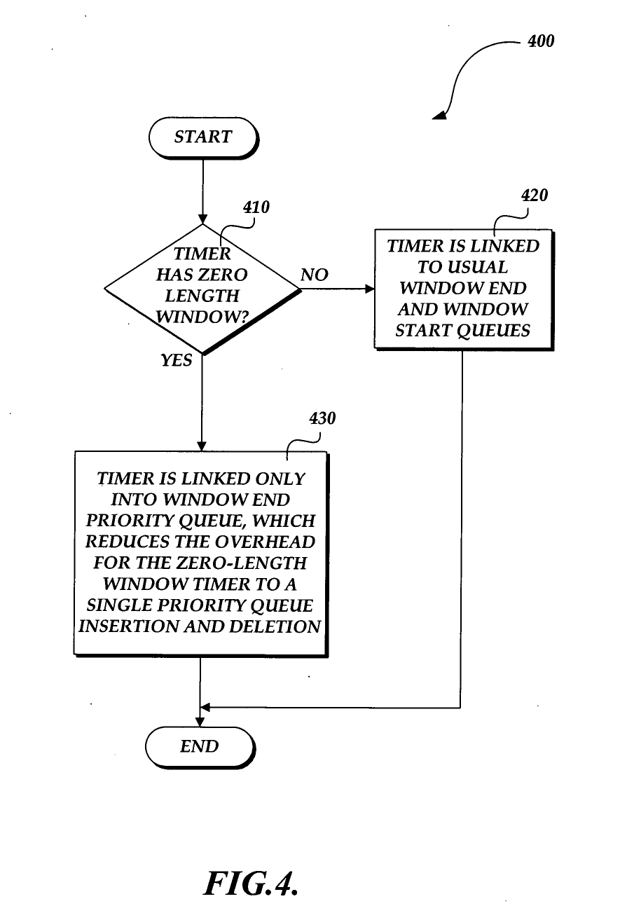

FIG. 4 is a flow diagram illustrative of a routine 400 for a timer with a zero-length window. At a decision block 410, a determination is made as to whether a timer has a zero-length window. If the timer does not have a zero-length window, then the routine continues to a block 420, where the timer is linked to the usual window end and window start queues. If the timer does have a zero-length window, then the routine continues to a block 430, where the timer is linked only into the window end priority queue, which reduces the overhead for the zero-length window timer to a single priority queue insertion and deletion.

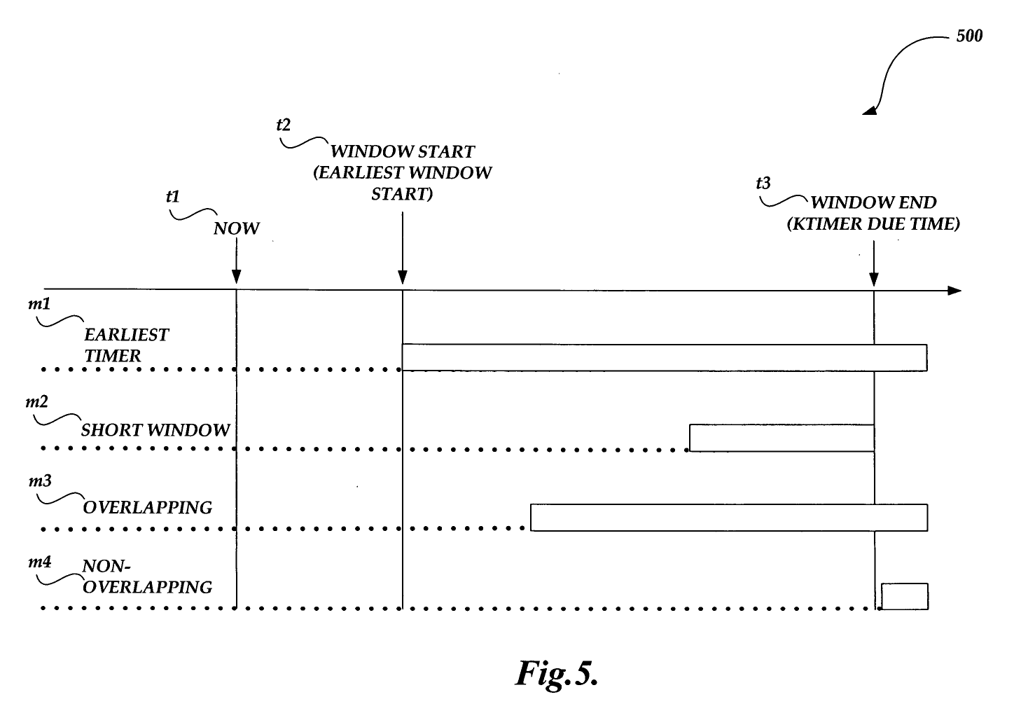

FIG. 5 is a timing diagram 500 illustrating multiple timers with varying start and end times. Four timers are shown, including an earliest timer M1, a short window timer M2, an overlapping timer M3, and a non-overlapping timer M4. Three time periods are indicated, including a now time T1, a window start time T2 (representative of an earliest window start), and a window end time T3 (representative of the earliest window end, which is the due time of the underlying timer). The earliest timer M1 is shown to start at the window start time T2 and end after the window end time T3. The short window timer M2 is shown to start after the window start time T2 and end at the window end time T3. The overlapping timer M3 is shown to start after the window start time T2 and end after the window end time T3. The non-overlapping timer M4 is shown to start and end after the window end time T3.

The timing diagram 500 of FIG. 5 is useful for illustrating certain aspects of the embodiment of the present invention. As noted above, in accordance with the present invention, an interface is provided for setting a timer to expire at some point within a given window of time, instead of expiring at a specific time. This makes it possible to expire timers in a batch instead of one at a time, thus reducing the overhead of expiring multiple timers and improving the scalability of the system. As noted above, in one embodiment, this is implemented by using two priority queues per pool (e.g., window start and window end priority queues), and ordering the timers by their window start and window end times. The per-pool priority queues are used to isolate the timers. The timing diagram 500 of FIG. 5 shows a variety of timers, including their window start and window end times. It should be noted that the earliest timer window start is not necessarily the timer which should be used for the due time; this is why two priority queues are necessary. To determine the underlying kernel timer's expiration time, the window end priority queue is maintained to include all of the currently active timers ordered by the earliest window end time, and the system peeks at the front of the queue—this is the latest time at which the underlying kernel timer can fire and still provide correct behavior. In other words, when expiring timers, the window end priority queue is insufficient by itself, in that there may be timers which can and should be expired, but whose window end times are later than the window end times of the timers which should not be expired (e.g., see the earliest timer M1 and the non-overlapping timer M4 in FIG. 5). Thus, the system also maintains a window start priority queue of the currently active timers ordered by their earliest start time first. To expire timers, the system removes timers from the window start and window end priority queues until the timer at the front of each queue has a window start time that is later than the current time.

As described above, the embodiment of the present invention provides a mechanism for managing actions that need only be started within a specified interval. By exploiting windows of acceptable times for events, timer expirations can be grouped and processed in batches to improve the throughput of the system. In one embodiment, an action is associated with a timer object, which has start and end times that specify an interval during which the associated action should be started. A pair of priority queues orders timers by their earliest start times and their earliest end times. These times are compared with the current time, and corresponding timers are retired from the queues until the timers at the front of each of the queues have a start time that is later than the current time.

While the preferred embodiment of the invention has been illustrated and described, it will be appreciated that various changes can be made therein without departing from the spirit and scope of the invention.

The embodiments of the invention in which an exclusive property or privilege is claimed are defined as follows:

1. A system for timer windows comprising:
a window start priority queue which includes currently active timers ordered by their earliest start times; and
a window end priority queue which includes currently active timers ordered by their earliest window end times.

2. The system of claim 1, wherein for the window end priority queue, the expiration time of the timer at the front of the queue is utilized as the expiration time of the underlying timer.

3. The system of claim 1, wherein in order to expire timers, timers are removed from the front of the window start queue until the timer at the front of the queue has a window start time later than the current time.

4. The system of claim 1, wherein for a timer with a zero-length window, the timer is linked only into the window end priority queue, and in order to expire the timers, timers are removed from the front of both the window start queue and the window end queue until the timer at the front of each queue has a window start time later than the current time.

5. The system of claim 1, wherein a hardware timer is utilized as an underlying timer.

6. The system of claim 1, wherein a kernel-mode timer is utilized as an underlying timer.

7. A method for timer windows, comprising:
ordering a plurality of timer windows for a plurality of tasks by their earliest window end times; and
grouping a plurality of the tasks together such that they can be processed and the associated timers expired as a group.

8. The method of claim 7, wherein the timer windows are further ordered according to their window start times.

9. The method of claim 8, wherein window start and window end priority queues are utilized for ordering the timers.

10. The method of claim 9, wherein for the window end priority queue, the expiration time of the timer at the front of the queue is used as the expiration time of the underlying timer.

11. The method of claim 9, wherein in order to expire timers, timers are removed from the front of the window start priority queue until the timer at the front of the queue has a window start time later than the current time.

12. The method of claim 9, wherein for a timer with a zero-length window, the timer is linked only into the window end priority queue, and in order to expire timers, timers are removed from the front of both the window start priority queue and the window end priority queue, until the timer at the front of each queue has a window start time later than the current time.

13. The method of claim 7, wherein a hardware timer is utilized as an underlying timer.

14. The method of claim 7, wherein a kernel-mode timer is utilized as an underlying timer.

15. One or more computer-readable media for enabling a computer-program segment to communicate with one or more other computer-program segments for providing timer windows, said media comprising:
a set of computer-usable instructions for grouping a plurality of timer windows such that they can be processed together and their timer windows expired as a group.

16. The media of claim 15, further comprising a window end priority queue which includes currently active timers ordered by their earliest window end times.

17. The media of claim 16, further comprising a window start priority queue which includes currently active timers ordered by their earliest start times.

18. The media of claim 17, wherein for the window end priority queue, the expiration time of the timer at the front of the queue is utilized as the expiration time of the underlying timer.

19. The media of claim 17, wherein in order to expire timers, timers are removed from the front of the window start priority queue until the timer at the front of the queue has a window start time later than the current time.

20. The media of claim 17, wherein for a timer with a zero-length window, the timer is linked only into the window end priority queue, and in order to expire timers, timers are removed from the front of both the window start priority queue and the window end priority queue, until the timer at the front of each queue has a window start time later than the current time.
